(19) United States
(12) Patent Application Publication
(10) Pub. No.: US 2026/0156811 A1
(43) Pub. Date: Jun. 4, 2026

(54) SEMICONDUCTOR MEMORY DEVICE

(71) Applicant: SAMSUNG ELECTRONICS CO., LTD., Suwon-si (KR)

(72) Inventor: Juyeon Shin, Suwon-si (KR)

(21) Appl. No.: 19/177,359

(22) Filed: Apr. 11, 2025

(30) Foreign Application Priority Data
Oct. 18, 2024 (KR) 10-2024-0143320

(51) Int. Cl. H10B 12/00; H10D 1/68; H10W 20/43

(52) U.S. Cl. CPC H10B 12/50; H10B 12/315; H10B 12/318; H10B 12/34; H10D 1/716; H10W 20/43

(57) ABSTRACT

A semiconductor memory device includes a memory cell region including a memory cell and a core/peripheral region including a capacitor. The capacitor includes a lower electrode to which a first potential level is applied through a first metal pattern and that is formed on the core/peripheral region and an upper electrode to which a second potential level lower than the first potential level is applied through a second metal pattern and that is formed over the lower electrode. The capacitor has a first reliability breakdown voltage when a voltage higher than a voltage applied to the upper electrode is applied to the lower electrode and has a second reliability breakdown voltage lower than the first reliability breakdown voltage when a voltage lower than the voltage applied to the upper electrode is applied to the lower electrode.

### CROSS-REFERENCE TO RELATED APPLICATION

This application claims priority under 35 U.S.C. § 119 to Korean Patent Application No. 10-2024-0143320 filed on Oct. 18, 2024, in the Korean Intellectual Property Office, the entirety of which is incorporated by reference herein.

### BACKGROUND

Semiconductor devices have attracted attention as an important element in the electronics industry due to their characteristics such as small size, multi-functionality, and/or low manufacturing cost. The semiconductor devices may be classified into a semiconductor memory device that stores logic data, a semiconductor logic device that operates and processes logic data, and a hybrid semiconductor device including a memory element and a logic element.

Recently, with the high speed and low power consumption of electronic devices, semiconductor devices embedded in the electronic devices also require fast operating speed and/or low operating voltage. In order to meet these requirements, highly integrated semiconductor devices are required. However, with the high integration of semiconductor devices, the reliability and electrical characteristics of the semiconductor devices may be decreased. Accordingly, studies are being conducted to improve the reliability and electrical characteristics of semiconductor devices.

### SUMMARY

Some aspects of the present disclosure provide semiconductor memory devices with improved reliability and electrical characteristics.

In some implementations, a semiconductor memory device includes a memory cell region including a memory cell and a core/peripheral region including a capacitor. The capacitor includes a lower electrode to which a first potential level is applied through a first metal pattern and that is formed on the core/peripheral region and an upper electrode to which a second potential level lower than the first potential level is applied through a second metal pattern and that is formed over the lower electrode. The capacitor has a first reliability breakdown voltage when a voltage higher than a voltage applied to the upper electrode is applied to the lower electrode and has a second reliability breakdown voltage lower than the first reliability breakdown voltage when a voltage lower than the voltage applied to the upper electrode is applied to the lower electrode.

In some implementations, a semiconductor memory device includes a memory cell region including a memory cell and a core/peripheral region including a first capacitor and a second capacitor. The first capacitor includes a first lower electrode to which a first potential level is applied through a first metal pattern and that is formed on the core/peripheral region and a first upper electrode to which a second potential level lower than the first potential level is applied through a second metal pattern and that is formed over the first lower electrode. The second capacitor includes a second lower electrode to which the first potential level is applied through a third metal pattern connected with the first metal pattern and that is formed on the core/peripheral region and a second upper electrode to which the second potential level is applied through a fourth metal pattern connected with the second metal pattern and that is formed over the second lower electrode. The first capacitor has a first reliability breakdown voltage when a voltage higher than a voltage applied to the first upper electrode is applied to the first lower electrode and has a second reliability breakdown voltage lower than the first reliability breakdown voltage when a voltage lower than the voltage applied to the first upper electrode is applied to the first lower electrode. The second capacitor has a third reliability breakdown voltage when a voltage higher than a voltage applied to the second upper electrode is applied to the second lower electrode and has a fourth reliability breakdown voltage lower than the third reliability breakdown voltage when a voltage lower than the voltage applied to the second upper electrode is applied to the second lower electrode.

In some implementations, a semiconductor memory device includes a memory cell region including a memory cell and a core/peripheral region including a first capacitor unit and a second capacitor unit. The first capacitor unit includes a first capacitor and a second capacitor connected in parallel, and the second capacitor unit includes a third capacitor and a fourth capacitor connected in parallel. Each of the first to fourth capacitors includes a lower electrode to which a first potential level is applied through first to fourth metal patterns connected with one another and that is formed on the core/peripheral region and an upper electrode to which a second potential level lower than the first potential level is applied through fifth to eighth metal patterns connected with one another and that is formed over the lower electrode. Each of the first to fourth capacitors has a first reliability breakdown voltage when a voltage higher than a voltage applied to the upper electrode is applied to the lower electrode and has a second reliability breakdown voltage lower than the first reliability breakdown voltage when a voltage lower than the voltage applied to the upper electrode is applied to the lower electrode.

### BRIEF DESCRIPTION OF THE DRAWINGS

The above and other objects and features of the present disclosure will become apparent by describing in detail examples thereof with reference to the accompanying drawings.

FIG. 1 is a block diagram illustrating an example of a memory system including a memory device.

FIG. 2 is a plan view of an example of a memory device.

FIG. 3A is a plan view illustrating a portion of a memory cell region.

FIG. 3B is a sectional view taken along line T-T′ in FIG. 3A.

FIG. 4 is a sectional view of a memory device, where the sectional view corresponds to the direction of a cross-section taken along line S-S′ of FIG. 2.

FIG. 5 is a sectional view of the memory device of FIG. 2 including metal wiring, where the sectional view is taken along line S-S′ of FIG. 2.

FIG. 6 is a graph illustrating reliability evaluation for the metal wiring of FIG. 4 and the metal wiring of FIG. 5.

FIG. 7 is a sectional view taken along line S-S′ of FIG. 2.

FIG. 8 is a schematic view illustrating a wiring layer connecting two capacitors in series and an equivalent circuit of the capacitors.

FIG. 9 is a schematic view illustrating a wiring layer connecting two capacitors in parallel and an equivalent circuit of the capacitors.

FIG. 10 is a schematic view illustrating a wiring layer connecting two capacitor units in series and an equivalent circuit of capacitors.

FIG. 11 is a schematic view illustrating a wiring layer connecting two capacitor units in parallel and an equivalent circuit of the capacitors.

FIG. 12 is a schematic view illustrating a wiring layer connecting four capacitors in series and an equivalent circuit of the capacitors.

FIG. 13 is a schematic view illustrating a wiring layer connecting four capacitors in series in two stages and an equivalent circuit of the capacitors.

FIG. 14 is a schematic view illustrating a wiring layer connecting a plurality of capacitors in series in three stages and a corresponding equivalent circuit.

### DETAILED DESCRIPTION

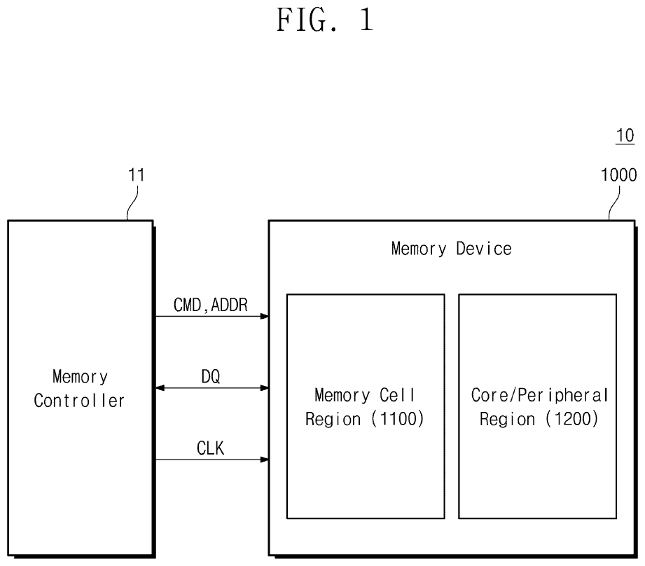

FIG. 1 is a block diagram illustrating a memory system 10 including a memory device 1000 according to some implementations of the present disclosure. Referring to FIG. 1, the memory system 10 may include a memory controller 11 and the memory device 1000.

The memory controller 11 may control overall operation of the memory system 10 and may control overall data exchange between an external host device and the memory device 1000. For example, the memory controller 11 may generate a command CMD and an address ADDR in response to a request of the host device and may write data represented by a data signal DQ to the memory device 1000 or may read data from the memory device 1000, based on the command CMD and the address ADDR. For example, the memory controller 11 may provide, to the memory device 1000, a clock signal CLK for writing data or reading data.

The memory device 1000 may include a memory cell region 1100 and a core/peripheral region 1200. The memory device 1000 may be a semiconductor memory device and may be a volatile memory device or a non-volatile memory device. For example, the memory device 1000 may be a dynamic random access memory (DRAM) device, a synchronous DRAM (SDRAM) device, or the like. Hereinafter, the memory device 1000 will be taken as a DRAM device. However, other types of memory devices are also within the scope of this disclosure.

The memory cell region 1100 may include a plurality of memory cells for storing data. For example, the memory cell region 1100 may include a memory cell array in which the plurality of memory cells are arranged in a plurality of rows and columns. The memory cell array may include the plurality of memory cells. The plurality of memory cells may be connected with word lines and bit lines, respectively. In some implementations, each of the plurality of memory cells may be a dynamic random access memory (DRAM) cell. However, the types of memory cells are not limited thereto.

In some implementations, each of the plurality of memory cells may include one transistor and one capacitor. However, other numbers of transistor and/or capacitor are also within the scope of this disclosure.

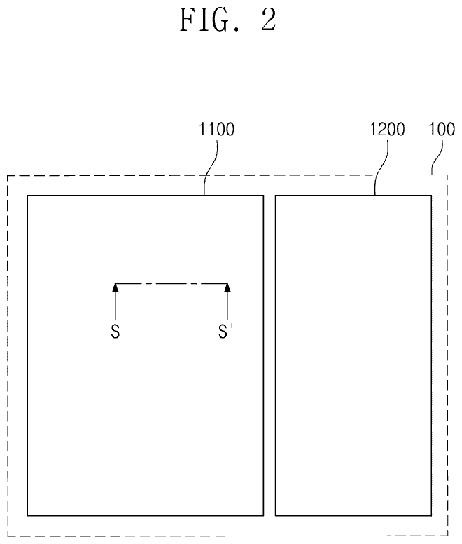

The core/peripheral region 1200 may include peripheral circuits related to the memory cell array. For example, the core/peripheral region 1200 may include a plurality of circuits for writing, reading, and managing data related to the memory cells. A more detailed description thereof will be given below with reference to FIG. 2.

FIG. 2 is a plan view of a memory device according to some implementations of the present disclosure. Referring to FIG. 2, the memory cell region 1100 and the core/peripheral region 1200 may be formed on a substrate 100 corresponding to the memory device 1000 of FIG. 1.

The core/peripheral region 1200 may be formed near the memory cell region 1100. For example, the core/peripheral region 1200 may be formed side by side with the memory cell region 1100 on the same plane. The core/peripheral region 1200 may include elements that perform power pumping, voltage divider, and decoupling.

The core/peripheral region 1200 may include a decoupling capacitor for performing a decoupling operation and a pumping capacitor for performing a power pumping operation.

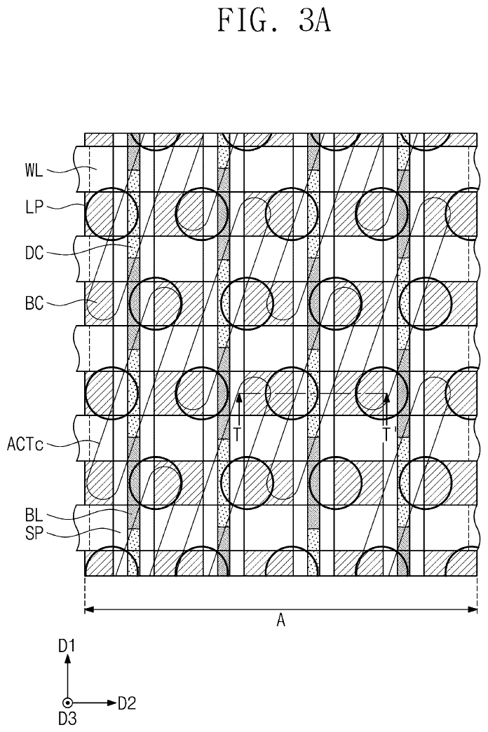

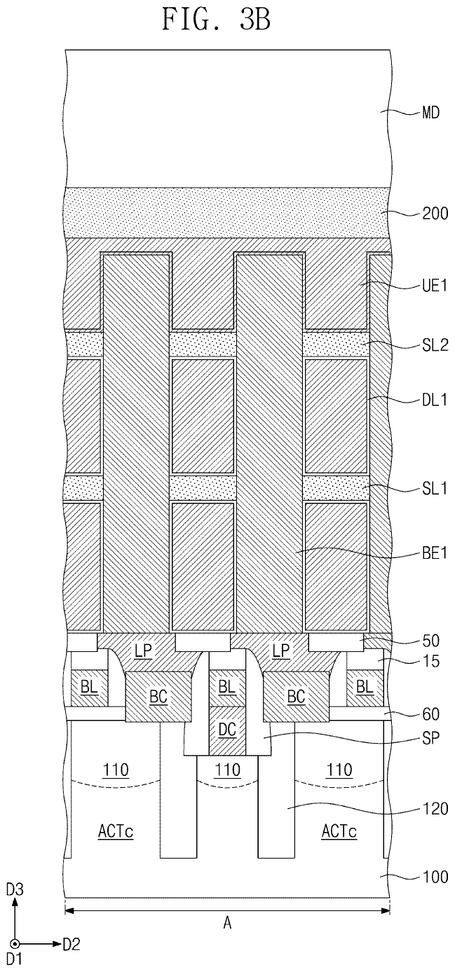

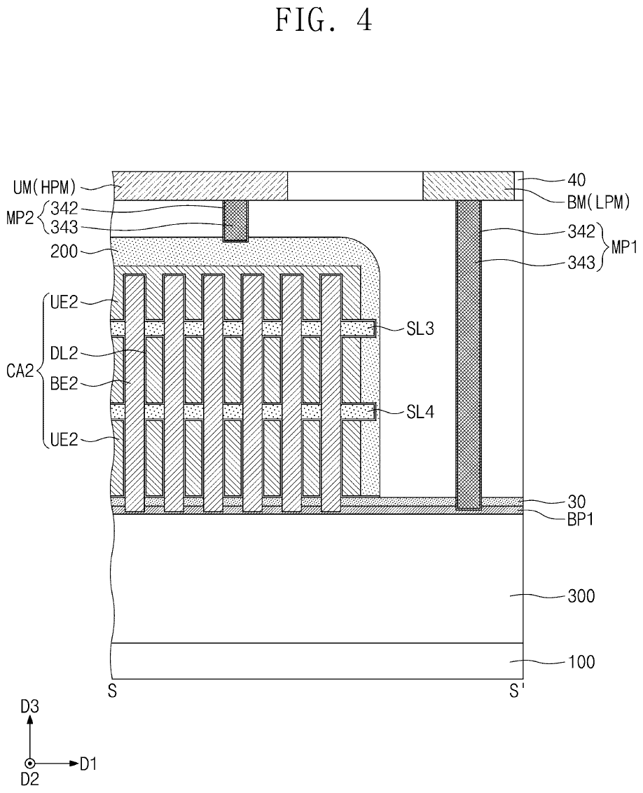

In some implementations, a decoupling capacitor structure and a pumping capacitor structure may be formed in the same manner as a capacitor (e.g., DRAM cell capacitor) structure of a memory cell in the memory cell region 1100. A more detailed description thereof will be given below with reference to FIGS. 3A-3B and 4.

FIG. 3A is a plan view illustrating a portion of a memory cell region according to some implementations of the present disclosure. Referring to FIG. 3A, a plan view of a portion (memory cell region A) of the memory cell region 1100 of FIG. 2 is illustrated. FIG. 3B is a sectional view taken along line T-T′ in FIG. 3A.

In this specification, a first direction D1 is defined as a direction parallel to an upper surface of the semiconductor substrate 100. A second direction D2 is defined as a direction parallel to the upper surface of the semiconductor substrate 100 and perpendicular to the first direction D1. A third direction D3 is defined as a direction perpendicular to the upper surface of the semiconductor substrate 100.

Referring to FIGS. 3A and 3B, cell activation patterns ACTc may be disposed on the memory cell region of the semiconductor substrate 100.

As illustrated in FIG. 3A, the cell activation patterns ACTc may be spaced apart from one another in the first direction D1 and the second direction D2 when viewed in the plan view. The cell activation patterns ACTc may have a bar shape parallel to the upper surface of the semiconductor substrate 100 and extending in a diagonal direction crossing the first direction D1 and the second direction D2.

As illustrated in FIG. 3B, device isolation layers 120 may be disposed between the cell activation patterns ACTc on the memory cell region A. The device isolation layers 120 may be disposed inside the semiconductor substrate 100 to define the cell activation patterns ACTc.

A isolation layers 120 may be disposed between the memory cell region A and the core/peripheral region. The isolation layers 120 may separate the memory cell region A and the core/peripheral region from each other.

Word lines WL may cross the cell activation patterns ACTc and the device isolation layers 120 on the memory cell region A. The word lines WL may be disposed in grooves formed on the cell activation patterns ACTc and the device isolation layers 120. The word lines WL may extend in the second direction D2 and may be spaced apart from one another in the first direction D1. The word lines WL may be embedded in the semiconductor substrate 100. A cell gate insulating layer may be interposed between the word lines WL and the semiconductor substrate 100, and word line capping patterns may be disposed on the word lines WL. Upper surfaces of the word line capping patterns may be coplanar with the upper surface of the semiconductor substrate 100. An impurity region 110 may be included in an upper portion of the semiconductor substrate 100 on the word line WL side. The impurity region 110 may correspond to a source or drain region.

An interlayer insulating layer 60 may be disposed on the upper surface of the semiconductor substrate 100. A lower surface of the interlayer insulating layer 60 may be in contact with upper surfaces of the device isolation layers 120 and the upper surface of the semiconductor substrate 100. The interlayer insulating layer 60 may include an insulating material. The insulating material may include, for example, at least one of silicon nitride and silicon oxide.

As illustrated in FIGS. 3A and 3B, bit lines BL crossing the word lines WL may be provided on the memory cell region A of the semiconductor substrate 100. The bit lines BL may extend in the first direction D1 and may be spaced apart from one another in the second direction D2. The interlayer insulating layer 60 may enclose a bit line contact plug DC, and the bit lines BL may be spaced apart from the semiconductor substrate 100 with the interlayer insulating layer 60 therebetween. A side surface of each of the bit lines BL may be covered by a bit line spacer SP. Upper surfaces of the bit lines BL may be covered by bit line capping patterns 15. The bit line capping patterns 15 may include an insulating material such as a silicon nitride layer. The impurity region 110 may be connected with lower electrode contact plugs BC. Landing pads LP may be disposed on the lower electrode contact plugs BC. The landing pads LP may be insulated from one another by an interlayer insulating layer 50. The interlayer insulating layer 50 may include an insulating material. The insulating material may include, for example, at least one of silicon nitride and silicon oxide. The lower electrode contact plugs BC may include an impurity-doped poly silicon pattern, and the landing pads LP may include a barrier metal layer and a metal. The barrier metal layer may include, for example, a titanium/titanium nitride layer. The metal may include, for example, tungsten. The bit line spacer SP may extend in the first direction D1 on each of the bit lines BL. The bit line contact plug DC may be interposed between the bit line BL and the impurity region 110 and may electrically connect the bit line BL and the impurity region 110.

First lower electrodes BE1 may be disposed on the landing pads LP so as to be spaced apart from one another in the first direction D1. The first lower electrodes BE1 may include at least one of impurity-doped poly silicon, metal nitride such as titanium nitride, and a metal layer such as tungsten, aluminum, or copper. Each of the first lower electrodes BE1 may have a cylindrical shape or a hollow cylinder or cup shape. A second support pattern SL2 may support upper sidewalls of the first lower electrodes BE1, and a first support pattern SL1 may support lower sidewalls of the first lower electrodes BE1. The first and second support patterns SL1 and SL2 may include an insulating material such as silicon nitride, silicon oxide, or silicon oxy nitride.

A first capacitor dielectric DL1 may cover surfaces of the first lower electrodes BE1 and surfaces of the first and second support patterns SL1 and SL2. The first capacitor dielectric DL1 may include, for example, at least one of silicon oxide, silicon nitride, silicon oxy nitride, and a high-k material. A first upper electrode UE1 may be disposed over the first capacitor dielectric DL1 and may fill spaces between the first lower electrodes BE1. The first upper electrode UE1 may include at least one of an impurity-doped poly silicon layer, metal nitride such as titanium nitride, and a metal layer such as tungsten, aluminum, or copper. The first lower electrodes BE1, the first capacitor dielectric DL1, and the first upper electrode UE1 may constitute a first capacitor.

A plate 200 may be disposed on the first capacitor. The plate 200 may include SiGe or a metallic material. The first capacitor may be connected with a metal pattern in a wiring layer of the plate 200 through a metal plug MP.

FIG. 4 is a sectional view of a memory device including comparative metal wiring, where the sectional view corresponds to the direction of a cross-section taken along line S-S′ of FIG. 2. Referring to FIG. 4, a plan view of a portion of a core/peripheral region is illustrated. In FIG. 4, components having the same reference numerals and symbols as the components illustrated in FIGS. 3A and 3B may correspond to the components illustrated in FIGS. 3A and 3B, respectively. For convenience of description, repetitive descriptions identical to ones given with reference to FIGS. 3A and 3B will be omitted.

On the core/peripheral region, an intermediate layer 300 including an interlayer insulating layer, a peripheral capping pattern, and an impurity region may be formed on the substrate 100. A first pad BP1 may be disposed on the intermediate layer 300. The peripheral capping pattern may cover an upper surface of the interlayer insulating layer of the intermediate layer 300. The peripheral capping pattern may include at least one of silicon nitride, silicon oxide, and silicon oxy nitride.

A second capacitor CA2 may be disposed on the first pad BP1. The second capacitor CA2 may include a second upper electrode UE2, second lower electrodes BE2, and a second capacitor dielectric DL2. The second lower electrodes BE2 may be spaced apart from one another in the first direction D1, and portions of lower ends of the second lower electrodes BE2 may be connected with the first pad BP1. The portions of the lower ends of the second lower electrodes BE2 may be disposed to penetrate portions of the first pad BP1. The second lower electrodes BE2 may include the same material as the first lower electrodes BE1. The second lower electrodes BE2 may have a pillar shape or a cylindrical shape. Although not illustrated, the first pad BP1 may be connected with the impurity region of the intermediate layer 300 (e.g., the impurity region 110 of FIG. 3) through at least one contact.

A third support pattern SL3 and a fourth support pattern SL4 that extend in the first direction D1 may be provided. The fourth support pattern SL4 may support upper sidewalls of the second lower electrodes BE2, and the third support pattern SL3 may support lower sidewalls of the second lower electrodes BE2.

The second capacitor dielectric DL2 may cover surfaces of the second lower electrodes BE2 and surfaces of the third and fourth support patterns SL3 and SL4. The second capacitor dielectric DL2 may include the same material as the first capacitor dielectric DL1. The second upper electrode UE2 may be disposed on the second capacitor dielectric DL2 and may fill spaces between the second lower electrodes BE2. The second upper electrode UE2 may include the same material as the first upper electrode UE1.

An interlayer insulating layer 30 may be disposed on the first pad BP1. The interlayer insulating layer 30 may include an insulating material. The insulating material may include, for example, at least one of silicon nitride and silicon oxide.

A plate 200 may be disposed on the interlayer insulating layer 30. The plate 200 may have a shape that covers the second capacitor CA2, and the shape of the plate 200 is not limited to the shape illustrated in the drawing. The plate 200 may include SiGe or a metallic material.

A wiring layer 40 may be disposed over the second capacitor CA2. A metal pattern may be included in or formed by the wiring layer 40. The metal pattern may include an upper metal pattern UM and a lower metal pattern BM. The lower metal pattern BM may be connected with the second lower electrodes BE2 through a first metal plug MP1 and the first pad BP1. The upper metal pattern UM may be connected with the second upper electrode UE2 through a second metal plug MP2 and the plate 200.

Capacitors may have different connection relationships within a plurality of circuits in the memory device depending on the reliability of the capacitors. For example, the number of capacitors included in each circuit, the connection relationship between the capacitors, and the connection relationship between the capacitors and other elements may vary to satisfy the capacitance, the critical leakage current amount, and the lifetime required by the circuit.

For example, when a voltage greater than or equal to the reliability breakdown voltage of a capacitor is applied to the capacitor, the reliability of the capacitor may be deteriorated. When the reliability of the capacitor is deteriorated, a leakage current exceeding a critical leakage current may occur, or the lifetime of the capacitor may be reduced. Due to this, the performance of a memory device may be degraded. Accordingly, circuits (e.g., a decoupling circuit and a voltage pumping circuit) including the capacitor may be designed such that a voltage greater than the reliability breakdown voltage is not applied to the capacitor.

In some implementations, the reliability breakdown voltage may correspond to a critical voltage that causes a leakage current exceeding the critical leakage current to occur in the capacitor. Alternatively, or in addition, the reliability breakdown voltage may correspond to a critical voltage at which the capacitor is damaged or destroyed before its reference lifetime. For example, the reliability breakdown voltage, the critical leakage current, and the reference lifetime may be values previously determined through experiments, machine learning, and the like.

Capacitors may be classified into a capacitor (e.g., a 1-series capacitor) that is not connected in series to another capacitor and a capacitor (e.g., a 2-series capacitor or a 4-series capacitor) that is connected in series to another capacitor.

In general, the reliability breakdown voltage of the 1-series capacitor is determined based on the case in which the first potential level applied to the lower metal pattern BM of the capacitor is lower than the second potential level applied to the upper metal pattern UM. Accordingly, in the design of memory devices, reliability may be secured by connecting capacitors in the form of the 2-series capacitor or the 4-series capacitor when a voltage exceeding the reliability breakdown voltage is applied.

According to some implementations of the present disclosure, a potential level higher than the potential level applied to the upper metal pattern UM may be applied to the lower metal pattern BM to improve the reliability breakdown voltage of the capacitor. In addition, in a 2-series capacitor or 4-series capacitor, by modifying the potential level applied to the upper metal pattern UM or the lower metal pattern BM of each capacitor and the connection relationship between the capacitors, it is possible to decrease the number of capacitors while maintaining the same capacitance or to increase the capacitance while maintaining the number of capacitors. In some implementations, a metal pattern (e.g., the lower metal pattern BM) to which a lower potential level is applied may be referred to as a low-potential metal pattern LPM, and a metal pattern (e.g., the upper metal pattern UM) to which a higher potential level is applied may be referred to as a high-potential metal pattern HPM.

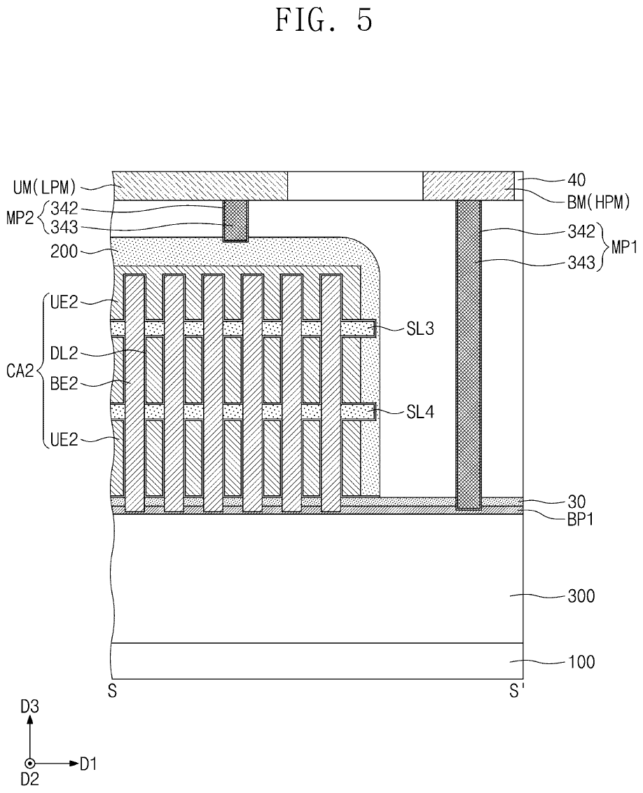

FIG. 5 is a sectional view of the memory device of FIG. 2 including metal wiring according to the present disclosure, where the sectional view corresponds to the direction of a cross-section taken along line S-S′ of FIG. 2. Referring to FIG. 5, a plan view of a portion of the core/peripheral region is illustrated. In FIGS. 5 and 4, components having the same reference numeral or symbol may correspond to each other. For convenience of description, repetitive descriptions identical to ones given with reference to FIG. 4 will be omitted.

A wiring layer 40 of FIG. 5 includes an upper metal pattern UM and a lower metal pattern BM. Unlike in FIG. 4, the potential level of the lower metal pattern BM may be higher than the potential level of the upper metal pattern HM. For example, the first potential level applied to the lower metal pattern BM may be higher than the second potential level applied to the upper metal pattern UM.

Accordingly, the lower metal pattern BM may be referred to as a high-potential metal pattern HPM, and the upper metal pattern UM may be referred to as a low-potential metal pattern LPM.

In some implementations, the metal wiring of FIG. 5 may be formed by interchanging the upper metal pattern UM and the lower metal pattern BM of FIG. 4. For example, by changing the metal wiring in the wiring layer 40 without changing the configuration or connection relationship from the substrate 100 to the second capacitor CA2 in the third direction D3, a potential level higher than the potential level applied to the second upper electrode UE2 may be applied to the second lower electrode BE2 of the second capacitor CA2.

In some implementations, the memory device may include a power supply circuit. The power supply circuit may output a plurality of power signals (or voltage signals) having different potential levels. The power supply circuit may receive a raw power signal from an external source of the memory device and generate a plurality of power signals (or voltage signals) based on the raw power signal. The power supply circuit may provide different power signals (or voltage signals) to the lower metal pattern (BM) and the upper metal pattern (UM). For example, the lower metal pattern BM may be configured to receive a high potential level from the power supply circuit, and the upper metal pattern UM may be configured to receive a low potential level from the power supply circuit. Further, changing the metal wiring in the wiring layer 40 described above may be equivalent to changing the power signals (or voltage signals) that the power supply circuit applies to the lower metal pattern BM and the upper metal pattern UM.

However, the wiring and connection configurations are not limited thereto, and in some implementations a separate wiring layer may be added (e.g., on the substrate 100) such that the second lower electrode BE2 has a higher potential level than the second upper electrode UE2.

As compared with when the second lower electrode BE2 has a lower potential level than the second upper electrode UE2, the reliability of the second capacitor CA2 may be improved when the second lower electrode BE2 has a higher potential level than the second upper electrode UE2.

For example, when the second lower electrode BE2 has a higher potential level than the second upper electrode UE2, the first reliability breakdown voltage of the second capacitor CA2 may be a first voltage (or, a first potential difference). When the second lower electrode BE2 has a lower potential level than the second upper electrode UE2, the second reliability breakdown voltage of the second capacitor CA2 may be a second voltage (or, a second potential difference) lower than the first voltage.

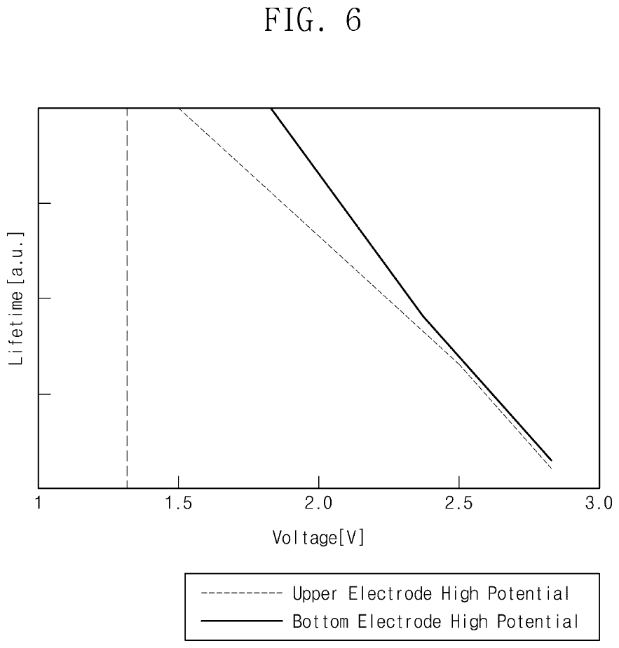

A more detailed description thereof will be given below with reference to FIG. 6.

FIG. 6 is a graph for illustrating reliability evaluation for the metal wiring of FIG. 4 and the metal wiring of FIG. 5. FIG. 6 depicts lifetime versus voltage in relation to the reliability of a capacitor when an upper electrode of the capacitor has a higher potential level than a lower electrode (e.g., the metal wiring of FIG. 4) (illustrated by a dotted line). In addition, FIG. 6 depicts lifetime versus voltage in relation to the reliability of a capacitor when a lower electrode of the capacitor has a higher potential level than an upper electrode (e.g., the metal wiring of FIG. 5) (illustrated by a solid line).

The horizontal axis of the graph represents, and the vertical axis of the graph represents lifetime. In some implementations, charging the capacitors up to a target voltage and discharging the capacitors from the target voltage may be rapidly repeated, and the lifetimes corresponding to the number of repetitions may be thereby evaluated.

In some implementations, a capacitor dielectric of a capacitor (e.g., the second capacitor CA2 of FIG. 5) may be a multilayer dielectric. The multilayer dielectric may include a plurality of dielectric layers. Each of the plurality of dielectric layers may be parallel to a surface of a lower electrode, and the plurality of dielectric layers may be stacked in a direction perpendicular to the surface of the lower electrode.

For example, the dielectric of the capacitor may include a first dielectric layer and a second dielectric layer. The first dielectric layer may be located between the lower electrode and the second dielectric layer, and the second dielectric layer may be located between the first dielectric layer and an upper electrode. The first dielectric layer and the second dielectric layer may be formed of different materials.

Accordingly, the electrical characteristics viewed in the direction from the upper electrode to the lower electrode of the capacitor and the electrical characteristics viewed from the lower electrode to the upper electrode of the capacitor may be asymmetrical to each other. For example, the lifetime, capacitance, or critical leakage current may vary depending on which of the lower and upper electrodes has a higher potential level.

However, the capacitor configuration is not limited thereto, and, even when the dielectric of the capacitor is a single dielectric, other factor(s), such as treatment of the lower electrode, the type and amount of impurity included in the process of forming the upper electrode, and/or other reasons may result in asymmetry in capacitor characteristics, such that lifetime/reliability is improved when a higher voltage is applied to the lower electrode.

Referring again to the graph of FIG. 6, when the lower electrode has a higher potential level, the lifetime is longer than when the upper electrode has a higher potential level. In particular, the lifetime difference tends to increase as the charge/discharge experimental voltage decreases from about 2.3 V.

For example, the lifetime difference may increase by several thousand times or more in the range of about 1.1 V to about 1.2 V, which is the range of voltage that the memory device receives from the outside.

The capacitor to which the metal wiring is applied may have improved reliability when compared to the capacitor to which comparative metal wiring is applied. Accordingly, in some implementations, a memory device including a capacitor having an increased lifetime, a reduced leakage current, and an increased reliability breakdown voltage may be provided.

Accordingly, in some implementations, a decoupling circuit including the capacitor with improved reliability may achieve a reduction in the time required to stabilize a supply voltage. Furthermore, a pumping circuit including the capacitor with improved reliability may achieve an increase in efficiency, such as a decrease in the number of required capacitors and a reduction in occupied area.

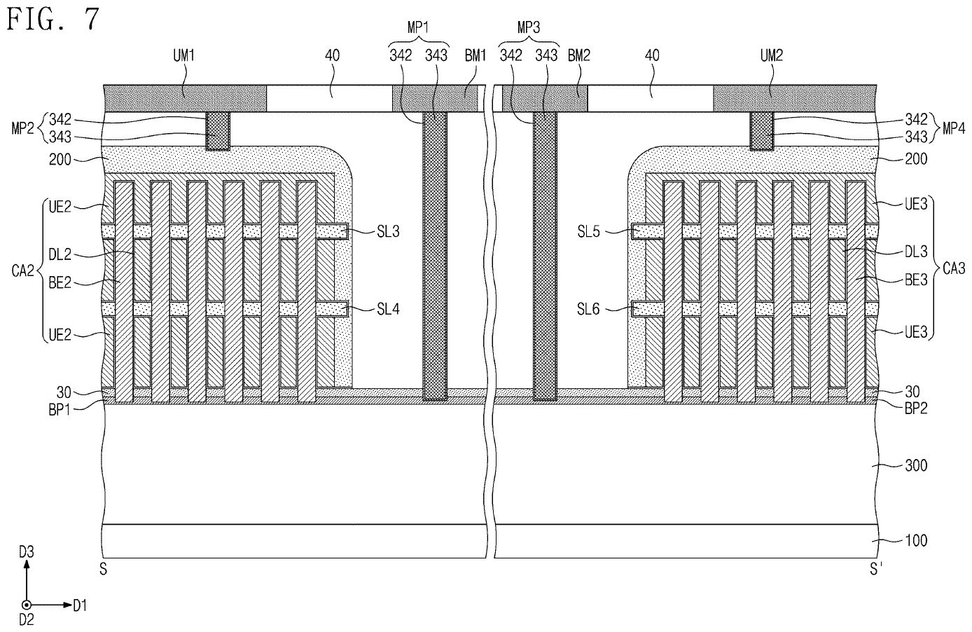

In addition, in some implementations, as the reliability breakdown voltage increases, the number of capacitors required for a peripheral circuit may be decreased so that the size of a memory device may be reduced, or increased capacitance may be provided even though the same number of capacitors are provided. A more detailed description thereof will be given below with reference to FIGS. 7 and 15.

FIG. 7 is a sectional view taken along line S-S′ of FIG. 2. Referring to FIG. 7, a peripheral circuit in the core/peripheral region includes a plurality of capacitors.

The peripheral circuit may include a second capacitor CA2 (e.g., corresponding to the second capacitor CA2 of FIGS. 4 and 5) and a third capacitor CA3. Similarly to the second capacitor CA2, the third capacitor CA3 may be formed between the substrate 100 and the wiring layer 40. For convenience of description, repetitive descriptions will hereinafter be omitted.

The second capacitor CA2 corresponds to the second capacitor CA2 of FIGS. 4 and 5, a first upper metal pattern UM1 corresponds to the upper metal pattern UM of FIG. 4 or 5, and a first lower metal pattern BM1 corresponds to the lower metal pattern BM1 of FIG. 4 or 5.

The third capacitor CA3 may be spaced apart from the second capacitor CA2 in the first direction D1. Like to the second capacitor CA2 disposed on the first pad BP1, the third capacitor CA3 may be disposed on a second pad BP2.

The third capacitor CA3 may include a third upper electrode UE3, third lower electrodes BE3, and a third capacitor dielectric DL3. The third lower electrodes BE3 may be spaced apart from one another in the first direction D1. Lower ends of the third lower electrodes BE3 may have a shape connected with the second pad BP2. Portions of the lower ends of the third lower electrodes BE3 may be disposed to penetrate portions of the second pad BP2. The third lower electrodes BE3 may be formed of a conductive material. For example, the third lower electrodes BE3 may be formed of impurity-doped poly silicon or may be formed of a metal containing layer such as a titanium nitride layer. The third lower electrodes BE3 may have a pillar shape or a cylindrical shape.

A fifth support pattern SL5 and a sixth support pattern SL6 that extend in the first direction D1 may be provided between the third lower electrodes BE3. The fifth support pattern SL5 may support upper sidewalls of the third lower electrodes BE3, and the sixth support pattern SL6 may support lower sidewalls of the third lower electrodes BE3. The fifth support pattern SL5 and the sixth support pattern SL6 may include, for example, a material such as silicon nitride, silicon oxide, or silicon oxy nitride.

The third capacitor dielectric DL3 may cover surfaces of the third lower electrodes BE3 and surfaces of the fifth and sixth support patterns SL5 and SL6. The third capacitor dielectric DL3 may include, for example, at least one of silicon oxide, silicon nitride, silicon oxy nitride, and a high-k material. The third upper electrode UE3 may be disposed on the third capacitor dielectric DL3 and may fill spaces between the third lower electrodes BE3. The third upper electrode UE3 may include at least one of an impurity-doped poly silicon layer, metal nitride such as titanium nitride, and a metal layer such as tungsten, aluminum, or copper.

The wiring layer 40 may be disposed over the third capacitor CA3. A metal pattern may be included in the wiring layer 40. The metal pattern may include a second upper metal pattern UM2 and a second lower metal pattern BM2.

A third metal plug MP3 may be connected to the second pad BP2. The third metal plug MP3 may include a diffusion barrier pattern 342 and a metal pillar 343 on the diffusion barrier pattern 342. The diffusion barrier pattern 342 may include, for example, metal nitride (e.g., TiN, TSN, TaN, or the like). The metal pillar 343 may include a metallic material such as tungsten, aluminum, or the like. The upper end of the third metal plug MP3 may be connected with the metal pattern included in the wiring layer 40. The third metal plug MP3 may be disposed in the third direction D3 perpendicular to the upper surface of the second pad BP2. A fourth metal plug MP4 may electrically connect the plate 200 on the third capacitor CA3 and the wiring layer 40.

Although only two capacitors CA2 and CA3 are illustrated in the circuit of FIG. 7, the spirit and scope of the present disclosure is not limited thereto, and the peripheral circuit may include three or more capacitors.

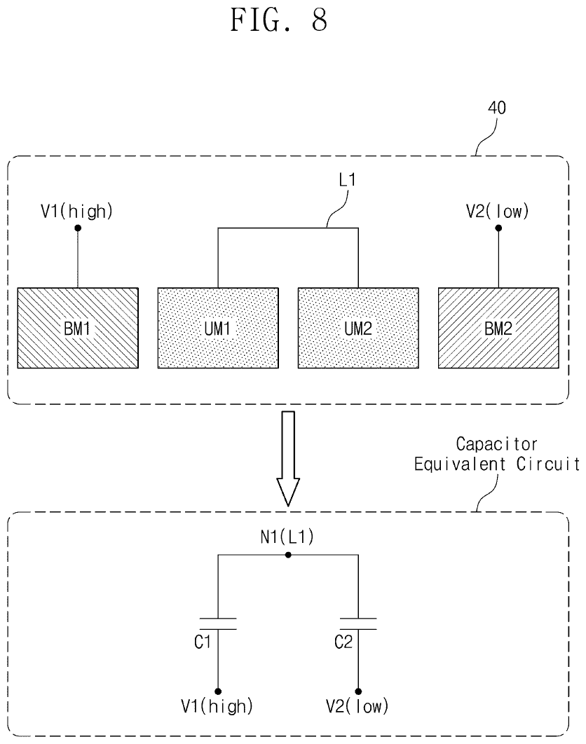

FIG. 8 is a schematic view illustrating a comparative wiring layer 40 connecting two capacitors in series and an equivalent circuit of the capacitors. Referring to FIG. 8, the wiring layer 40 may include a first lower metal pattern BM1, a first upper metal pattern UM1, a second lower metal pattern BM2, a second upper metal pattern UM2, and a first connecting pattern L1. The first lower metal pattern BM1, the first upper metal pattern UM1, the second lower metal pattern BM2, and the second upper metal pattern UM2 may correspond to the first lower metal pattern BM1, the first upper metal pattern UM1, the second lower metal pattern BM2, and the second upper metal pattern UM2 of FIG. 7, respectively.

A capacitor may have a first reliability breakdown voltage when a lower electrode has a higher potential level than an upper electrode. The capacitor may have a second reliability breakdown voltage lower than the first reliability breakdown voltage when the lower electrode has a lower potential level than the upper electrode.

In some implementations, a difference between a first potential level V1 and a second potential level V2 may be smaller than the first reliability breakdown voltage and greater than the second reliability breakdown voltage.

Accordingly, in the case in which the potential level applied to the lower electrode is lower than the potential level applied to the upper electrode in at least one of the first capacitor C1 and the second capacitor C2, the reliability of the corresponding capacitor and the performance of a memory device may be deteriorated when the corresponding capacitor is directly connected between the first potential level V1 and the second potential level V2.

In this case, for example, the first potential level V1 (high potential) may be applied to the first lower metal pattern BM1. The first upper metal pattern UM1 and the second upper metal pattern UM2 may be electrically connected through the first connecting line L1. The second potential level V2 (low potential) may be applied to the second lower metal pattern BM2.

In other words, referring to the equivalent circuit, the first capacitor C1 and the second capacitor C2 may be connected to a first node N1 between the first potential level V1 and the second potential level V2 and may be connected in series accordingly. For example, the first capacitor C1 may be connected between the first potential level V1 and the first node N1, and the second capacitor C2 may be connected between the first node N1 and the second potential level V2.

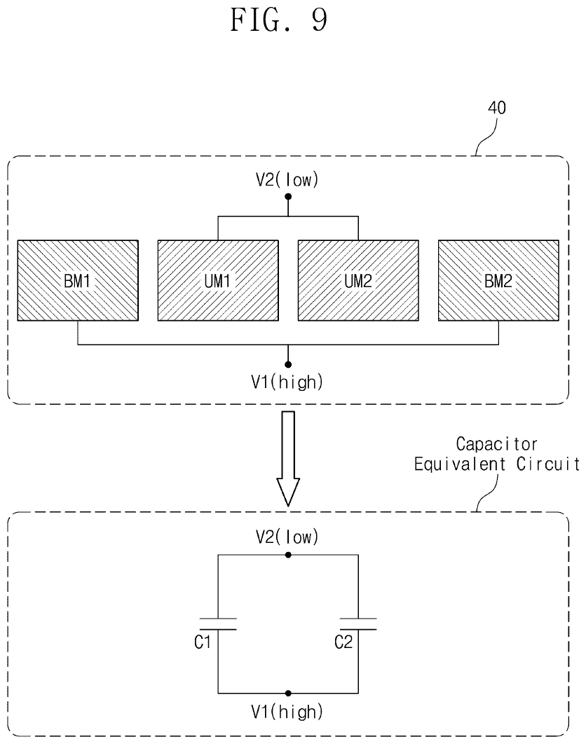

FIG. 9 is a schematic view illustrating a wiring layer connecting two capacitors in parallel and an equivalent circuit of the capacitors according to some implementations of the present disclosure. Referring to FIG. 9, a first lower metal pattern BM1, a first upper metal pattern UM1, a second lower metal pattern BM2, and a second upper metal pattern UM2 may correspond to the first lower metal pattern BM1, the first upper metal pattern UM1, the second lower metal pattern BM2, and the second upper metal pattern UM2 of FIG. 7, respectively.

Referring to FIG. 9, a case in which capacitors are connected between a first potential level V1 and a second potential level V2 as in FIG. 8 will be described below. When a lower electrode of a capacitor has a higher potential level than an upper electrode of the capacitor, the capacitor may have a first reliability breakdown voltage. When the difference between the first potential level V1 and the second potential level V2 is greater than the second reliability breakdown voltage but smaller than the first reliability breakdown voltage, the reliability is not deteriorated even though two capacitors are connected in parallel between the first potential level V1 and the second potential level V2.

For example, the first potential level V1 (high potential) may be applied to the first lower metal pattern BM1 and the second lower metal pattern BM2, and the second potential level V2 (low potential) may be applied to the first upper metal pattern UM1 and the second upper metal pattern UM2.

In some implementations, the first lower metal pattern BM1 and the second lower metal pattern BM2 may be connected, and the first upper metal pattern UM1 and the second upper metal pattern UM2 may be electrically connected.

In some implementations, the first lower metal pattern BM1 may be the same as the second lower metal pattern BM2.

In some implementations, the first upper metal pattern UM1 may be the same as the second upper metal pattern UM2.

Accordingly, two capacitors may be connected in parallel between the first potential level V1 and the second potential level V2. Thus, in FIG. 9, the number of capacitors is the same as that in FIG. 8, but the total capacitance may increase. For example, when the two capacitors have the same capacitance, the total capacitance of the equivalent circuit of FIG. 9 may be four times greater than the total capacitance of the equivalent circuit of FIG. 8.

Alternatively, instead of connecting two capacitors in parallel as in FIG. 9, one capacitor with improved reliability may be connected between the first potential level V1 and the second potential level V2, and thus the area occupied by the capacitor may be reduced.

Hereinafter, a case of including three or more capacitors as the capacitance required by a peripheral circuit gradually increases, a case of applying comparative metal wiring, and a case of applying metal wiring according to some implementations of the present disclosure will be described in detail. In the case of including three or more capacitors, the capacitors can be spaced apart from one another in the first direction D1 (or, the second direction D2) as in FIG. 7. Similarly to the second capacitor CA2 and the third capacitor CA3 of FIG. 7, the capacitors may be formed between the substrate 100 and the wiring layer 40.

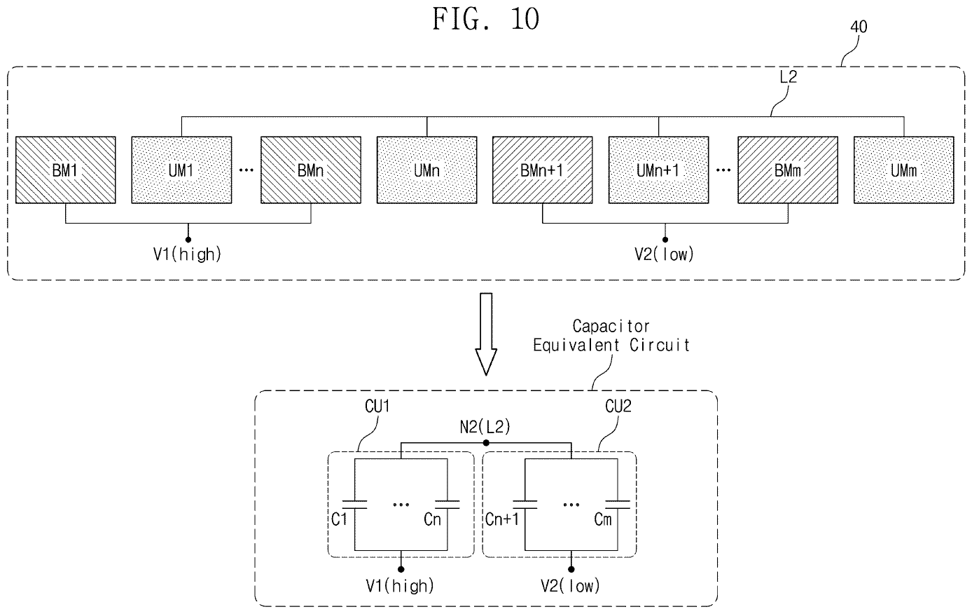

FIG. 10 is a schematic view illustrating a wiring layer 40 connecting two comparative capacitor units in series and an equivalent circuit of capacitors. A capacitor unit may include two or more capacitors connected in parallel. Referring to FIG. 10, a first capacitor unit CU1 includes n capacitors connected in parallel, and a second capacitor unit CU2 includes (m-n) capacitors. Here, n is a natural number greater than or equal to 2, and m is a natural number greater than or equal to (n+2).

The first capacitor unit CU1 may include first to n^{th} capacitors C1 to Cn. The first to n^{th} capacitors C1 to Cn may include first to n^{th} lower metal patterns BM1 to BMn, respectively, and may include first to n^{th} upper metal patterns UM1 to UMn, respectively.

The second capacitor unit CU2 may include (n+1)^{th} to m^{th} capacitors Cn+1 to Cm. The (n+1)^{th} to m^{th} capacitors Cn+1 to Cm may include (n+1)^{th} to m^{th} lower metal patterns BMn+1 to BMm, respectively, and may include (n+1)^{th} to m^{th} upper metal patterns UMn+1 to UMm, respectively.

When comparative metal wiring is applied, the first capacitor unit CU1 and the second capacitor unit CU2 may be connected in parallel between a first potential level V1 and a second potential level V2 as in FIG. 8, due to the limitation of the reliability breakdown voltage of at least one of the first to m^{th} capacitors C1 to Cm.

In some implementations, each of the first to m^{th} capacitors C1 to Cm may have a first reliability breakdown voltage when a potential level higher than the potential level applied to an upper electrode is applied to a lower electrode. In contrast, each of the first to m^{th} capacitors C1 to Cm may have a second reliability breakdown voltage lower than the first reliability breakdown voltage when a potential level lower than the potential level applied to the upper electrode is applied to the lower electrode. In this case, the difference between the first potential level V1 and the second potential level V2 may be greater than the second reliability breakdown voltage and smaller than the first reliability breakdown voltage.

For example, in the case in which a potential level lower than the potential level applied to the upper electrode is applied to the lower electrode in at least one of the first to m^{th} capacitors C1 to Cm, the performance of a memory device may be deteriorated when the corresponding capacitor is directly connected between the first potential level V1 and the second potential level V2.

Accordingly, referring to the wiring layer 40 of FIG. 10, the first potential level V1 (high potential) is applied to the first to n^{th} lower metal patterns BM1 to BMn. The second potential level V2 (low potential) is applied to the (n+1)^{th} to m^{th} lower metal patterns BMn+1 to BMm. The first to m^{th} upper metal patterns UM1 to UMm are connected with one another through a second connecting line L2.

In other words, referring to the equivalent circuit of FIG. 10, to ensure capacitor reliability, the first capacitor unit CU1 and the second capacitor unit CU2 may be connected in series between the first potential level V1 and the second potential level V2 through a second node N2 corresponding to the second connecting line L2.

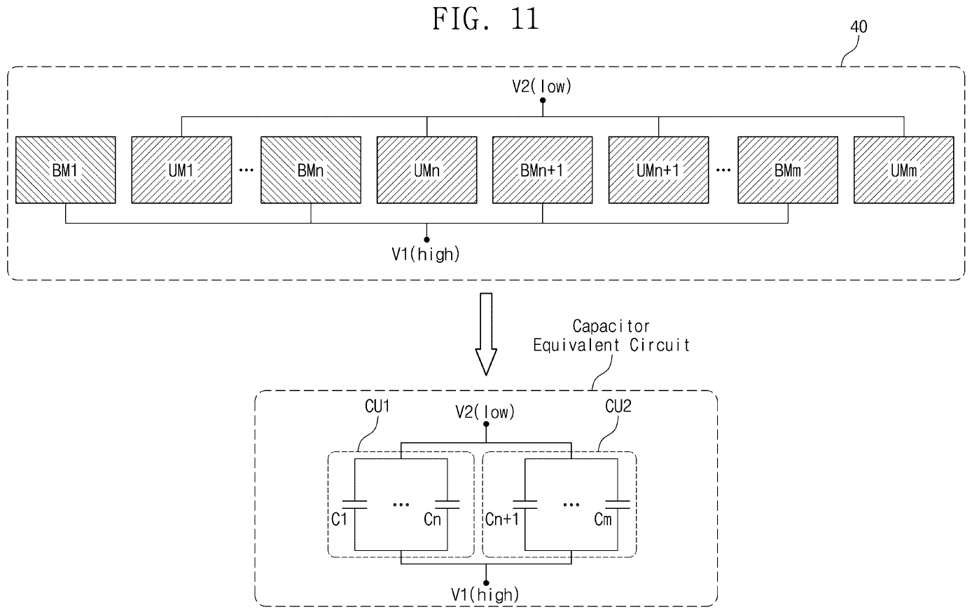

FIG. 11 is a schematic view illustrating a wiring layer 40 connecting two capacitor units in parallel and an equivalent circuit of capacitors according to some implementations of the present disclosure. A first capacitor unit CU1, a second capacitor unit CU2, first to m^{th} upper metal patterns UM1 to UMm, and first to m^{th} lower metal patterns BM1 to BMm of FIG. 11 may correspond to the components of FIG. 10 that have the same reference numerals.

A first potential level V1 (high potential) may be applied to the first to mth lower metal patterns BM1 to BMm. A second potential level V2 (low potential) may be applied to the first to m^{th} upper metal patterns UM1 to UMm.

Accordingly, a lower electrode of each of first to m^{th} capacitors C1 to Cm has a higher potential level than an upper electrode, and therefore the reliability breakdown voltage of each of the first to m^{th} capacitors C1 to Cm is a first reliability breakdown voltage. As described above with reference to FIG. 10, the first reliability breakdown voltage may be greater than the difference between the first potential level V1 and the second potential level V2. Accordingly, the first to m^{th} capacitors C1 to Cm may be directly connected between the first potential level V1 and the second potential level V2. That is, the first to m^{th} capacitors C1 to Cm may be connected in parallel between the first potential level V1 and the second potential level V2.

In addition, since the first to m^{th} capacitors C1 to Cm of FIG. 11 are all connected in parallel, the total capacitance may be greater than that when the first capacitor unit CU1 and the second capacitor unit CU2 are connected in series in FIG. 10.

Accordingly, in some implementations, when metal wiring is disposed such that the lower electrodes of the capacitors have a higher potential level than the upper electrodes, the total capacitance within the same area may be increased, or the area occupied by the capacitors may be reduced while the same total capacitance is maintained.

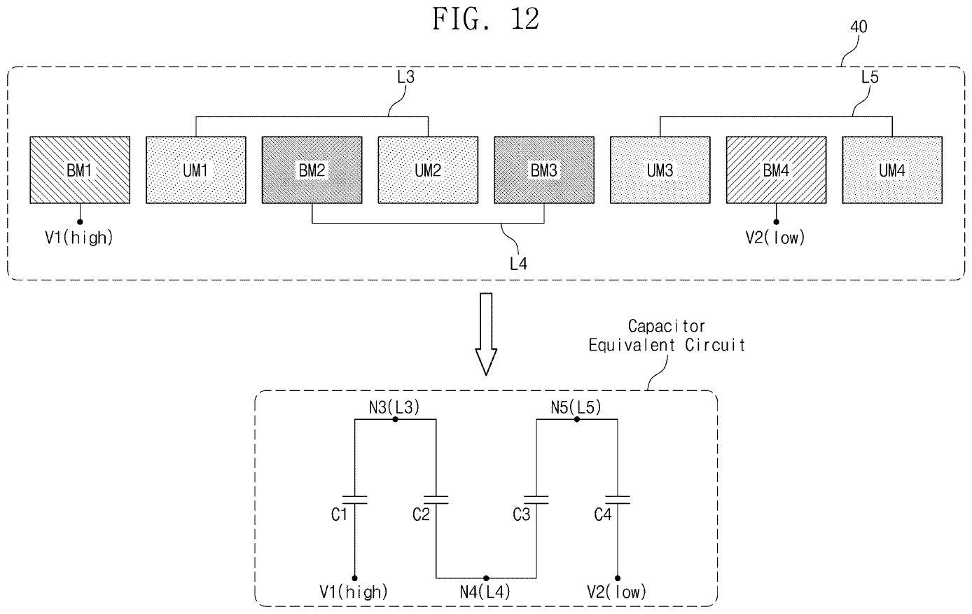

FIG. 12 is a schematic view illustrating a wiring layer 40 connecting four comparative capacitors in series and an equivalent circuit of the capacitors. Referring to FIG. 12, first to fourth capacitors C1 to C4 connected between a first potential level V1 and a second potential level V2 are illustrated.

The first to fourth capacitors C1 to C4 may be spaced apart from one another in the first direction D1 (or, the second direction D2) as in FIG. 7. The first to fourth capacitors C1 to C4 include first to fourth lower metal patterns BM1 to BM4, respectively. The first to fourth capacitors C1 to C4 include first to fourth upper metal patterns UM1 to UM4, respectively.

Due to the limitation of the reliability breakdown voltage of at least one of the first to fourth capacitors C1 to C4, the first to fourth capacitors C1 to C4 are connected in series between the first potential level V1 and the second potential level V2. For example, when the first to fourth capacitors C1 to C4 all have the same reliability breakdown voltage, the difference between the first potential level V1 and the second potential level V2 may be four times greater than the corresponding reliability breakdown voltage.

For example, the first potential level V1 may be applied to the first lower metal pattern BM1. The first upper metal pattern UM1 and the second upper metal pattern UM2 may be electrically connected through a third connecting line L3. The second lower metal pattern BM2 and the third lower metal pattern BM3 may be electrically connected through a fourth connecting line L4. The third upper metal pattern UM3 and the fourth upper metal pattern UM4 may be electrically connected through a fifth connecting line L5.

Referring to the equivalent circuit, a third node N3 corresponding to the third connecting line L3, a fourth node N4 corresponding to the fourth connecting line L4, and a fifth node N5 corresponding to the fifth connecting line L5 are illustrated between the first potential level V1 and the second potential level V2. The first capacitor C1 may be connected between the first potential level V1 and the third node N3. The second capacitor C2 may be connected between the third node N3 and the fourth node N4. The third capacitor C3 may be connected between the fourth node N4 and the fifth node N5. The fourth capacitor C4 may be connected between the fifth node N5 and the second potential level V2.

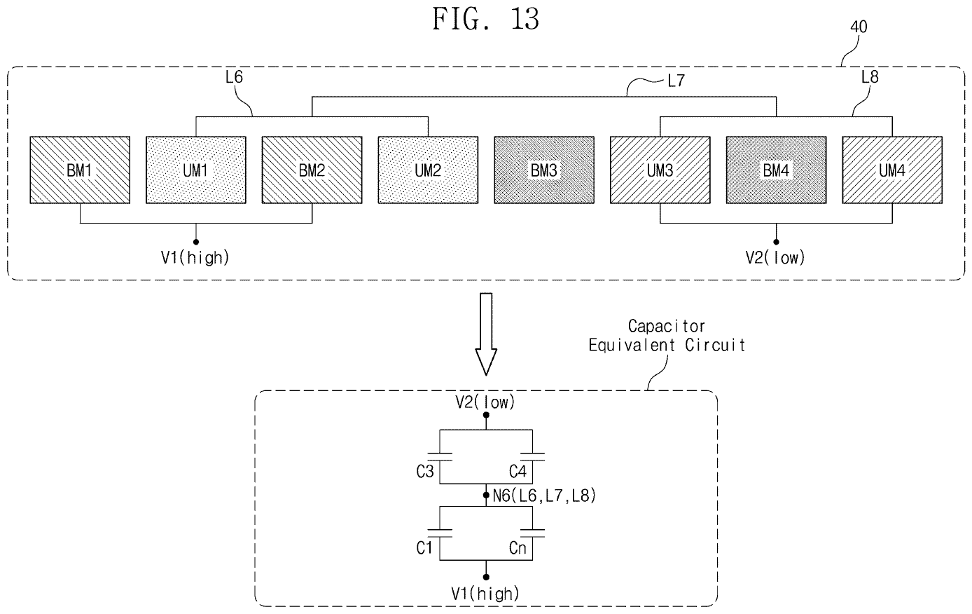

FIG. 13 is a schematic view illustrating a wiring layer 40 connecting four capacitors in series in two stages and an equivalent circuit of the capacitors according to some implementations of the present disclosure. Referring to FIG. 13, four capacitors are connected in series in two stages between a first potential level V1 and a second potential level V2 by changing the metal wiring of the wiring layer 40 of FIG. 12.

For example, the first potential level V1 is applied to a first lower metal pattern BM1 and a second lower metal pattern BM2. A first upper metal pattern UM1 and a second upper metal pattern UM2 are electrically connected through a sixth connecting line L6. A third lower metal pattern BM3 and a fourth lower metal pattern BM4 are electrically connected through an eighth connecting line L8. The sixth connecting line L6 and the eighth connecting line L8 are electrically connected through a seventh connecting line L7. However, the connections are not limited thereto, and the circuit connection relationship connecting the first to fourth capacitors C1 to C4 in series may vary.

Since the lower electrode of each of the first to fourth capacitors C1 to C4 has a higher potential level than the upper electrode, the reliability of each capacitor may be ensured even though the first to fourth capacitors C1 to C4 are connected in series in two stages between the first potential level V1 and the second potential level V2.

For example, the first to fourth capacitors may have the same reliability breakdown voltage. In this case, the difference between the first potential level V1 and the second potential level V2 may be smaller than twice the corresponding reliability breakdown voltage.

Referring to the equivalent circuit, a sixth node N6 between the first potential level V1 and the second potential level V2 may correspond to the sixth to eighth connecting lines L6 to L8. The first capacitor C1 and the second capacitor C2 may be connected in parallel between the first potential level V1 and the sixth node N6. The third capacitor C3 and the fourth capacitor C4 may be connected in parallel between the sixth node N6 and the second potential level V2.

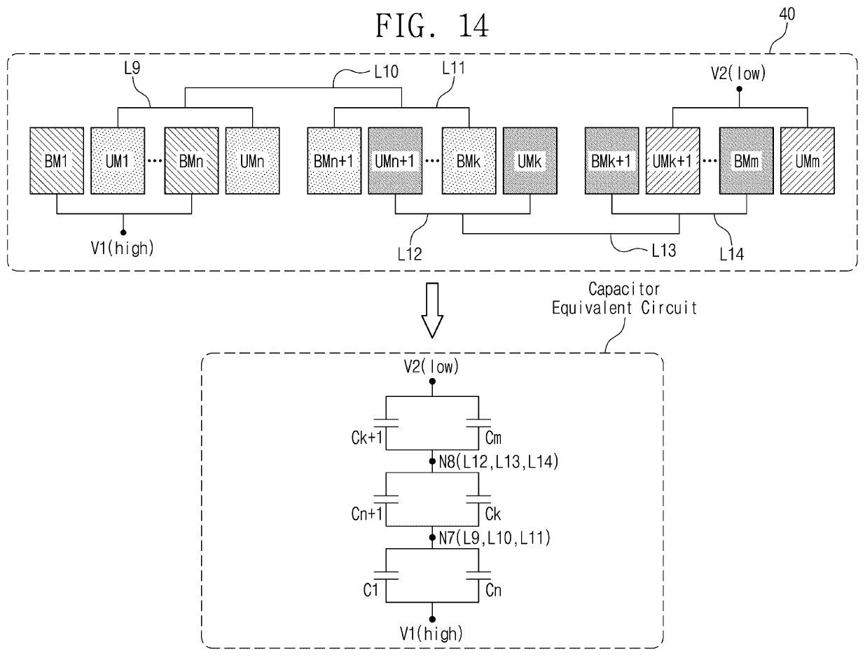

FIG. 14 is a schematic view illustrating a wiring layer 40 connecting a plurality of capacitors in series in three stages and an equivalent circuit according to some implementations of the present disclosure. Referring to FIG. 14, an example in which m capacitor units are connected in series in three stages between a first potential level V1 and a second potential level V2 is illustrated.

First to n^{th} capacitors C1 to Cn are connected with first to n^{th} lower metal patterns BM1 to BMn, respectively, and are connected with first to n^{th} upper metal patterns UM1 to UMn, respectively. (n+1)^{th} to k^{th} capacitors Cn+1 to Ck are connected with (k+1)^{th} to m^{th} lower metal patterns BMk+1 to BMm, respectively, and are connected with (k+1)^{th} to m^{th} upper metal patterns UMk+1 to UMm, respectively.

The first potential level V1 (high potential) may be applied to the first to n^{th} lower metal patterns BM1 to BMn. The first to nth upper metal patterns UM1 to UMn may be electrically connected through a ninth connecting line L9. The (n+1)^{th} to k^{th} lower metal patterns BMn+1 to BMk may be electrically connected through an eleventh connecting line L11. The ninth connecting line L9 and the eleventh connecting line L11 may be electrically connected through a tenth connecting line L10. The (n+1)^{th} to k^{th} upper metal patterns UMn+1 to UMk may be electrically connected with one another through a twelfth connecting line L12. The (k+1)^{th} to m^{th} lower metal patterns BMk+1 to BMm may be electrically connected with one another through a fourteenth connecting line L14. The twelfth connecting line L12 and the fourteenth connecting line L14 may be electrically connected through a thirteenth connecting line L13. The second potential level V2 (low potential) may be applied to the (k+1)^{th} to m^{th} upper metal patterns UMk+1 to UMm.

The lower electrode of each of the first to m^{th} capacitors C1 to Cm may have a higher potential level than the upper electrode.

In some implementations, the first to m^{th} capacitors C1 to Cm may have the same first reliability breakdown voltage. For example, when the difference between the first potential level V1 and the second potential level V2 is smaller than three times the first reliability breakdown voltage, the reliability of the first to m^{th} capacitors C1 to Cm may be ensured.

In contrast, when the lower electrode of at least one of the first to m^{th} capacitors C1 to Cm has a lower potential level than the upper electrode and has a second reliability breakdown voltage lower than the first reliability breakdown voltage, to secure target reliability, the same m capacitors may be connected in series in four or more stages as in FIG. 12.

Accordingly, in some implementations, since the lower electrodes of all capacitors have a higher potential level than the upper electrodes, the reliability of the capacitors may be improved. Accordingly, the total capacitance may be increased while the number of capacitors is maintained, or the number of capacitors may be decreased while the total capacitance is maintained, so that the area occupied by the capacitors may be reduced.

Accordingly, in some implementations, semiconductor memory devices with improved reliability and electrical characteristics can be provided.

In some implementations, in the capacitor where the reliability of the capacitor varies depending on which of the lower and upper electrodes has a higher potential level, a potential level higher than the potential level applied to the upper electrode is applied to the lower electrode. Accordingly, the reliability of the capacitor may be improved, the number of capacitors may be decreased while the capacitance of the memory device is maintained, or the capacitance may be increased while the number of capacitors is maintained.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to various examples, it will be apparent to those of ordinary skill in the art that various changes and modifications may be made thereto without departing from the spirit and scope of the present disclosure as set forth in the following claims.

What is claimed is:

1. A semiconductor memory device comprising:
a memory cell region including a memory cell; and
a core/peripheral region including a capacitor,
wherein the capacitor includes:
a lower electrode configured to receive a first potential level through a first metal pattern, wherein the lower electrode is on the core/peripheral region; and
an upper electrode configured to receive a second potential level, lower than the first potential level, through a second metal pattern, wherein the upper electrode is over the lower electrode, and
wherein the capacitor has:
a first reliability breakdown voltage based on a first voltage being applied to the lower electrode, the first voltage being higher than a voltage applied to the upper electrode; and
a second reliability breakdown voltage based on a second voltage being applied to the lower electrode, the second voltage being lower than the voltage applied to the upper electrode,
wherein the second reliability breakdown voltage is lower than the first reliability breakdown voltage.

2. The semiconductor memory device of claim 1, wherein the capacitor has a leakage current smaller than a critical leakage current of the capacitor based on the second potential level being applied to the upper electrode and the first potential level being applied to the lower electrode.

3. The semiconductor memory device of claim 1, wherein a difference between the first potential level and the second potential level is smaller than the first reliability breakdown voltage and greater than the second reliability breakdown voltage.

4. The semiconductor memory device of claim 1, wherein the capacitor further includes a capacitor dielectric between the lower electrode and the upper electrode,
wherein the lower electrode has a cylindrical shape,
wherein the capacitor dielectric covers a surface of the lower electrode, and
wherein the upper electrode covers a surface of the capacitor dielectric.

5. The semiconductor memory device of claim 1, wherein the capacitor further includes a capacitor dielectric between the lower electrode and the upper electrode,
wherein the capacitor dielectric includes a first dielectric layer and a second dielectric layer composed of different materials, and
wherein the first dielectric layer is disposed on the lower electrode, and wherein the second dielectric layer is disposed between the first dielectric layer and the upper electrode.

6. The semiconductor memory device of claim 1, wherein the capacitor is a decoupling capacitor.

7. The semiconductor memory device of claim 1, wherein the capacitor is a pumping capacitor.

8. The semiconductor memory device of claim 1, further comprising:
a wiring layer over the upper electrode, the wiring layer including the first metal pattern and the second metal pattern;
a first pad on the core/peripheral region, and a first metal plug connected with the first pad, wherein the first metal pattern is connected to the first metal plug, and wherein the lower electrode is configured to receive the first potential level through the first pad; and
a plate on the upper electrode, and a second metal plug on the plate, wherein the second metal pattern is connected to the second metal plug, and wherein the upper electrode is configured to receive the second potential level through the plate.

9. The semiconductor memory device of claim 1, wherein the memory cell includes a cell capacitor, and
wherein the capacitor in the core/peripheral region is identical to the cell capacitor.

10. The semiconductor memory device of claim 1, wherein the semiconductor memory device is a dynamic random access memory (DRAM) device.

11. A semiconductor memory device comprising:
a memory cell region including a memory cell; and
a core/peripheral region including a first capacitor and a second capacitor,
wherein the first capacitor includes:
a first lower electrode configured to receive a first potential level through a first metal pattern, wherein the first lower electrode is on the core/peripheral region; and
a first upper electrode configured to receive a second potential level, lower than the first potential level, through a second metal pattern, wherein the first upper electrode is over the first lower electrode,
wherein the second capacitor includes:
a second lower electrode configured to receive the first potential level through a third metal pattern connected to the first metal pattern, wherein the second lower electrode is on the core/peripheral region; and
a second upper electrode configured to receive the second potential level through a fourth metal pattern connected to the second metal pattern, wherein the second upper electrode is over the second lower electrode,
wherein the first capacitor has:
a first reliability breakdown voltage based on a first voltage being applied to the first lower electrode, the first voltage being higher than a voltage applied to the first upper electrode; and
a second reliability breakdown voltage based on a second voltage being applied to the first lower electrode, the second voltage being lower than the voltage applied to the first upper electrode, wherein the second reliability breakdown voltage is lower than the first reliability breakdown voltage, and
wherein the second capacitor has:
a third reliability breakdown voltage based on a third voltage being applied to the second lower electrode, the third voltage being higher than a voltage applied to the second upper electrode; and
a fourth reliability breakdown voltage based on a fourth voltage being applied to the second lower electrode, the fourth voltage being lower than the voltage applied to the second upper electrode, wherein the fourth reliability breakdown voltage is lower than the third reliability breakdown voltage.

12. The semiconductor memory device of claim 11, wherein the first capacitor has a leakage current smaller than a critical leakage current of the first capacitor based on the second potential level being applied to the first upper electrode and the first potential level being applied to the first lower electrode.

13. The semiconductor memory device of claim 11, wherein the first reliability breakdown voltage and the third reliability breakdown voltage are equal to each other,
wherein the second reliability breakdown voltage and the fourth reliability breakdown voltage are equal to each other, and
wherein a difference between the first potential level and the second potential level is greater than the second reliability breakdown voltage and smaller than the first reliability breakdown voltage.

14. The semiconductor memory device of claim 11, wherein the first capacitor further includes a first capacitor dielectric between the first lower electrode and the first upper electrode,
wherein the first lower electrode has a cylindrical shape,
wherein the first capacitor dielectric covers a surface of the first lower electrode, and
wherein the first upper electrode covers a surface of the first capacitor dielectric.

15. The semiconductor memory device of claim 11, further comprising a power decoupling circuit including the first capacitor and the second capacitor.

16. The semiconductor memory device of claim 11, further comprising a pumping circuit including the first capacitor and the second capacitor.

17. The semiconductor memory device of claim 11, wherein the memory cell includes a cell capacitor, and
wherein the first capacitor and the second capacitor identical to the cell capacitor.

18. The semiconductor memory device of claim 17, wherein the semiconductor memory device is a dynamic random access memory (DRAM) device.

19. The semiconductor memory device of claim 11, wherein (i) the first metal pattern is the same as the third metal pattern, (ii) the second metal pattern is the same as the fourth metal pattern, or both (i) and (ii).

20. A semiconductor memory device comprising:
a memory cell region including a memory cell; and
a core/peripheral region including a first capacitor unit and a second capacitor unit,
wherein the first capacitor unit includes a first capacitor and a second capacitor connected in parallel,
wherein the second capacitor unit includes a third capacitor and a fourth capacitor connected in parallel,
wherein each of the first to fourth capacitors includes:
a lower electrode configured to receive a first potential level through at least one of first to fourth metal patterns that are connected to one another, wherein the lower electrode is on the core/peripheral region; and
an upper electrode configured to receive a second potential level lower than the first potential level through at least one of fifth to eighth metal patterns connected to one another, wherein the upper electrode is over the lower electrode, and
wherein each of the first to fourth capacitors has:
a first reliability breakdown voltage based on a first voltage being applied to the lower electrode, the first voltage being higher than a voltage applied to the upper electrode; and
a second reliability breakdown voltage based on a second voltage being applied to the lower electrode, the second voltage being lower than the voltage applied to the upper electrode,
wherein the second reliability breakdown voltage is lower than the first reliability breakdown voltage.
